(19) United States
(12) Patent Application Publication
(10) Pub. No.: US 2009/0154275 A1
(43) Pub. Date: Jun. 18, 2009

(54) SEMICONDUCTOR DEVICE AND TESTING METHOD THEREOF

(75) Inventor: Yasuhiro MATSUMOTO, Tokyo (JP)

Correspondence Address: MCDERMOTT WILL & EMERY LLP, 600 13TH STREET, N.W., WASHINGTON, DC, 20005-3096, US

(73) Assignee: ELPIDA MEMORY, INC., Tokyo (JP)

(21) Appl. No.: 12/369,201

(22) Filed: Feb. 11, 2009

Related U.S. Application Data
(62) Division of application No. 11/436,723, filed on May 19, 2006.

(30) Foreign Application Priority Data
May 19, 2005 (JP) 2005-146446

(51) Int. Cl. G11C 7/06

(52) U.S. Cl. 365/205

(57) ABSTRACT

A semiconductor device includes a sense amplifier, a drive circuit that operatively supplies a predetermined potential to the sense amplifier, and disconnection transistors that are provided between the sense amplifier and the drive circuit. According to the present invention, the disconnection transistors can disconnect the sense amplifier from the drive circuit. Therefore, when the sense amplifier is disconnected from the drive circuit during at least a part of a period from when the word line is activated till when the sense amplifier is activated, outflow and inflow of charge from and into the bit line can be stopped immediately.

### TECHNICAL FIELD

The present invention relates to a semiconductor device and a method of testing the semiconductor device. Particularly, the present invention relates to a semiconductor device including a sense amplifier, and a method of testing the semiconductor device.

### BACKGROUND OF THE INVENTION

A DRAM (Dynamic Random Access Memory) is one of various kinds of semiconductor memory devices most suitable for a large capacity, and is widely used for a main memory and the like of a computer. The DRAM is excellent for use as a large-capacity memory because a memory structure of the DRAM is extremely simple as compared with those of other semiconductor memory devices.

In other words, a memory cell of the DRAM includes one cell capacitor and one cell transistor, and can store information based on charge stored in the cell capacitor. Charging and discharging of the cell capacitor is controlled by the cell transistor whose control electrode is connected to a word line. When the cell transistor is turned on, a storage electrode of the cell capacitor is connected to a bit line. As a result, information can be read from and written into the DRAM.

As described above, since the memory cell of the DRAM stores information based on the amount of charge stored in the cell capacitor, a deviation in the potential that appears in the bit line due to the reading of data is very small. Therefore, the bit line is connected with a sense amplifier that amplifies a small potential deviation due to the data reading. See Japanese Patent Application Laid-Open Nos. 2002-124086 and 2003-272383.

Generally, a sense amplifier has what is called a flip-flop configuration. In order to perform amplification operation in higher sensitivity and at a higher speed, a threshold voltage of a transistor that constitutes the sense amplifier needs to be set as low as possible. Coupled with recent decrease in the operation voltage of the DRAM to about 1.5 volts, transistors having a threshold voltage near 0 volt are currently used for the sense amplifier.

However, when the threshold voltages of transistors that constitute the sense amplifier become low, the following problems occur.

During a period from when a potential of the bit line varies due to activation of a word line till when the sense amplifier is activated, transistors that constitute the sense amplifier unnecessarily bring into an on state due to the deviation in the potential of the bit line. When the transistor is turned on before the sense amplifier is activated, charge flows out from the bit line to the sense amplifier, or charge flows into the bit line from the sense amplifier. As a result, data that appears in the bit line may possibly be destroyed.

In order to solve the above problems, threshold voltages of the transistors that constitute the sense amplifier can be set high. However, in this case, sensitivity of the sense amplifier becomes low, and therefore, sense operation becomes slow.

When much charge flows out from the bit line or when much charge flows into the bit line before the sense amplifier is activated, it becomes difficult to evaluate current leak that occurs in the bit line.

In other words, even when a test of evaluating current leak generated in the bit line is conducted, it is impossible to determine whether the potential of the bit line that decreases along lapse of time is attributable to the current leak or attributable to outflow of charge to the sense amplifier. Even when a reduction in the potential in the bit line is small in this test, there is a possibility that the current leak is compensated for by a flow of charge from the sense amplifier into the bit line. As described above, according to the conventional semiconductor device, it has been difficult to correctly evaluate current leak that occurs in the bit line.

### SUMMARY OF THE INVENTION

The present invention has been achieved to solve the above problems. It is an object of the invention to decrease an unnecessary outflow of charge from a bit line to a sense amplifier and an unnecessary flow of charge from the sense amplifier into the bit line, thereby preventing a destruction of data that appears in the bit line, without decreasing sensitivity of the sense amplifier.

It is another object of the present invention to provide a method of testing a semiconductor device that can evaluate a current leak that occurs in a bit line in higher precision.

The above and other objects of the present invention can be accomplished by a semiconductor device, comprising: at least one sense amplifier; a drive circuit that operatively supplies a predetermined potential to the sense amplifier; and at least one disconnector that is provided between the sense amplifier and the drive circuit and that can disconnect the sense amplifier from the drive circuit.

According to the present invention, a disconnector can disconnect a sense amplifier from a drive circuit. Therefore, during at least a part of a period from when a word line is activated till when the sense amplifier is activated, the sense amplifier is disconnected from the drive circuit. With this arrangement, outflow of charge from the bit line and flow of charge into the bit line can be immediately stopped.

Plural sense amplifiers can be connected to the drive circuit. In this case, capacitance of the drive circuit becomes relatively large from a viewpoint of the sense amplifier, and therefore, outflow and inflow of charge before the sense amplifier is activated become large. However, since the semiconductor device according to the present invention has the disconnector, the outflow and inflow of charge before the sense amplifier is activated can be effectively suppressed, even when plural sense amplifiers are connected to one drive circuit.

In this case, when each of the sense amplifiers has a disconnector, the outflow and inflow of charge can be most effectively suppressed.

Preferably, the drive circuit includes an activating circuit that supplies an operation voltage to the sense amplifiers, and an equalizer that equalizes the sense amplifiers. When the equalizer is provided, although data can be read fast and in high sensitivity, the capacitance of the drive circuit becomes larger from a viewpoint of the sense amplifier. However, since the semiconductor device according to the present invention has disconnectors, the outflow and inflow of charge can be effectively suppressed, even when the capacitance of the drive circuit from the viewpoint of the sense amplifier becomes larger due to the presence of the equalizer.

The above and other objects of the present invention can also be accomplished by a semiconductor device, comprising: a word line; a bit line; a memory cell that is connected to the bit line when the word line is activated; a sense amplifier that is connected to the bit line; an activating circuit that activates the sense amplifier by supplying an operation voltage to the sense amplifier; and a disconnector that disconnects the sense amplifier from the activating circuit during at least a part of a period from when the word line is activated till when the sense amplifier is activated.

In the present invention, the sense amplifier and the activating circuit are disconnected during at least a part of the period from when the word line is activated till when the sense amplifier is activated. With this arrangement, outflow of charge from the bit line and flow of charge into the bit line can be immediately stopped.

Preferably, the activating circuit includes a first activating transistor that is connected to between a first power supply potential and a higher output terminal, and a second activating transistor that is connected to between a second power supply potential and a lower output terminal. Preferably, the first activating transistor and the second activating transistor are sequentially set conductive. This is effective when there is a difference between a deviation in a threshold voltage of a P-channel MOS transistor and a deviation in a threshold voltage of an N-channel MOS transistor, among transistors that constitute the sense amplifier.

In other words, when a deviation in a threshold voltage of the P-channel MOS transistor is larger than a deviation in a threshold voltage of an N-channel MOS transistor, the second activating transistor is set conductive before the first activating transistor. On the other hand, when a deviation in a threshold voltage of the N-channel MOS transistor is larger than a deviation in a threshold voltage of the P-channel MOS transistor, the first activating transistor is set conductive before the second activating transistor.

In the former case, a disconnector is disposed between a higher node of the sense amplifier and a higher output terminal of the activating circuit. In the latter case, a disconnector is disposed between a lower node of the sense amplifier and a lower output terminal of the activating circuit.

A method of testing a semiconductor device according to the present invention comprising: a word line; a bit line; a memory cell that is connected to the bit line in response to activation of the word line; a sense amplifier that is connected to the bit line; and an activating circuit that activates the sense amplifier by supplying an operation voltage to the sense amplifier, wherein the sense amplifier is disconnected from the activating circuit during at least a part of a period from when the word line is activated till when the sense amplifier is activated, thereby evaluating a current leak that occurs in the bit line.

### BRIEF DESCRIPTION OF THE DRAWINGS

The above and other objects, features and advantages of this invention will become more apparent by reference to the following detailed description of the invention taken in conjunction with the accompanying drawings, wherein:

FIG. 1 is a circuit diagram showing relevant parts of a semiconductor device according to a preferred embodiment of the present invention;

FIG. 2 is a circuit diagram showing a sense amplifier and memory cells;

FIG. 3 is a timing diagram for explaining the operation of the semiconductor device according to a preferred embodiment of the present invention;

FIG. 4A is a circuit diagram of a part of the sense amplifier shown in FIG. 1;

FIG. 4B is a circuit diagram of the circuit shown in FIG. 4A from which a disconnection transistor is deleted;

FIG. 5 is a circuit diagram showing relevant parts of a semiconductor device according to another preferred embodiment of the present invention in which one disconnection transistor is assigned to two sense amplifiers;

FIG. 6 is a circuit diagram showing relevant parts of a semiconductor device according to still another preferred embodiment of the present invention from which the disconnection transistors of N-channel are omitted;

FIG. 7 is a timing diagram for explaining the operation of the semiconductor device shown in FIG. 6 when a control signal RSAN is activated before a control signal RSAP;

FIG. 8 is a circuit diagram showing relevant parts of a semiconductor device according to still another preferred embodiment of the present invention from which the disconnection transistors of P-channel are omitted; and

FIG. 9 is a timing diagram for explaining the operation of the semiconductor device shown in FIG. 8 when a control signal RSAP is activated before a control signal RSAN.

### DETAILED DESCRIPTION OF THE EMBODIMENTS

Preferred embodiments of the present invention will now be explained in detail with reference to the drawings.

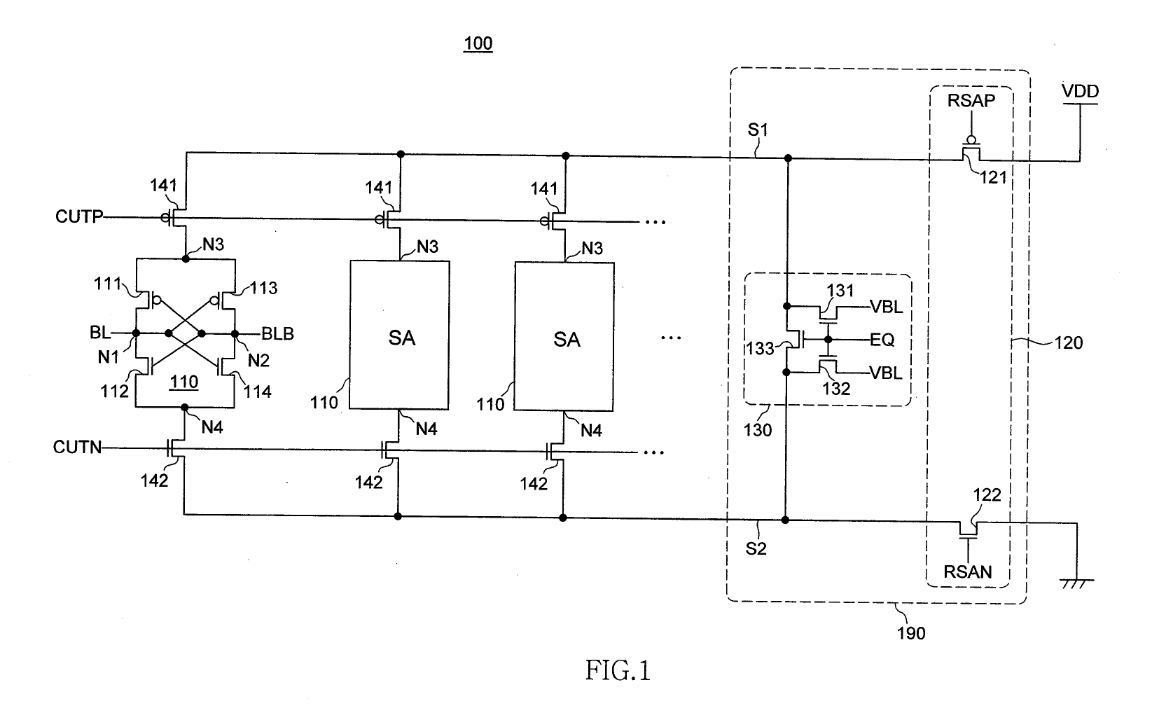

FIG. 1 is a circuit diagram showing relevant parts of a semiconductor device 100 according to a preferred embodiment of the present invention.

As shown in FIG. 1, the semiconductor device 100 according to the present embodiment includes plural sense amplifiers (SA) 110, an activating circuit 120 that supplies an operation voltage to the sense amplifiers 110, and an equalizer 130 that equalizes the sense amplifiers 110.

Among these circuits, the activating circuit 120 and the equalizer 130 constitute a drive circuit 190 that operatively supplies a predetermined potential such as an operation potential to the sense amplifiers 110. The phrase “operatively supply” refers to supplying a desired potential according to operation timing, instead of supplying a fixed potential as performed by a power supply circuit.

Each sense amplifier 110 has what is called a flip-flop configuration as shown in FIG. 1. Specifically, the sense amplifier 110 has a signal node N1 connected to a bit line BL, a signal node N2 connected to an inverted bit line BLB, a higher node N3 to which a first operation potential necessary for amplification is supplied, and a lower node N4 to which a second operation potential necessary for amplification is supplied.

A P-channel MOS transistor 111 is connected between the signal node N1 and the higher node N3, and an N-channel MOS transistor 112 is connected between the signal node N1 and the lower node N4. A P-channel MOS transistor 113 is connected between the signal node N2 and the higher node N3, and an N-channel MOS transistor 114 is connected between the signal node N2 and the lower node N4. The signal node N1 is connected in common to a gate electrode of the P-channel MOS transistor 113 and a gate electrode of the N-channel MOS transistor 114. The signal node N2 is connected in common to a gate electrode of the P-channel MOS transistor 111 and a gate electrode of the N-channel MOS transistor 112.

It is preferable to set threshold voltages of the transistors 111 to 114 that constitute the sense amplifier 110 to as low voltages as possible within a range not reaching 0 volt for the reason explained above. Preferably, the threshold voltages are set near 0 volt.

The semiconductor device 100 according to the present embodiment has plural sense amplifiers 110 thus configured. The drive circuit 190 constituted of the activating circuit 120 and the equalizer 130 is connected in common to the plural sense amplifiers 110.

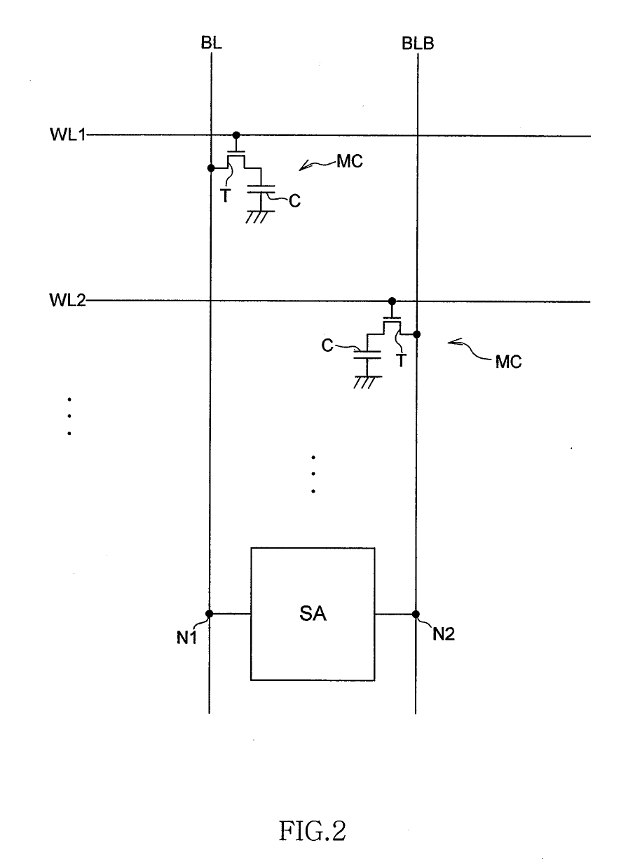

As shown in FIG. 2, memory cells MCs are connected to the bit line BL that is connected to the signal node N1, and to the inverted bit line BLB that is connected to the signal node N2. Each memory cell MC includes a series circuit of a cell transistor T and a cell capacitor C. A drain electrode of the cell transistor T is connected to a corresponding bit line BL or a corresponding inverted bit line BLB. A gate electrode of the cell transistor T is connected to a corresponding one of word lines WL1, WL2, and so forth.

With this arrangement, when a certain word line WLi becomes a high level, a cell capacitor C of the memory cell MC connected to this word line WLi is connected to a corresponding bit line BL or a corresponding inverted bit line BLB.

As shown in FIG. 1, the activating circuit 120 includes an activating transistor 121 that is connected between a power supply potential VDD (first power supply potential) and a higher output terminal S1, and an activating transistor 122 that is connected between a ground potential GND (second power supply potential) and a lower output terminal S2. The activating transistor 121 is a P-channel MOS transistor, and a control signal RSAP is supplied to a gate electrode of the activating transistor 121. On the other hand, the activating transistor 122 is an N-channel MOS transistor, and a control signal RSAN is supplied to a gate electrode of the activating transistor 122.

With this arrangement, when the activating transistor 121 is turned on, the power supply potential VDD is supplied to the higher output terminal S1. When the activating transistor 122 is turned on, the ground potential GND is supplied to the lower output terminal S2. Therefore, when both the activating transistors 121 and 122 are turned on, each sense amplifier 110 is activated, and a difference between bit line potentials that are supplied to the signal nodes N1 and N2 can be amplified.

The equalizer 130 is a circuit connected between the higher output terminal S1 and the lower output terminal S2. The equalizer 130 includes an N-channel MOS transistor 131 that is connected between the higher output terminal S1 and a precharge potential VBL, an N-channel MOS transistor 132 that is connected between the lower output terminal S2 and the precharge potential VBL, and an N-channel MOS transistor 133 that is connected between the higher output terminal S1 and the lower output terminal S2.

A control signal EQ is supplied in common to gate electrodes of the transistors 131 to 133. When the control signal EQ changes to a high level so as to activate the equalizer 130, potentials of the higher output terminal S1 and the lower output terminal S2 become the precharge potential VBL.

According to the semiconductor device in the present embodiment, a disconnection transistor 141 is provided between the higher node N3 of each sense amplifier 110 and the higher output terminal S1 of the drive circuit 190. Further, a disconnection transistor 142 is provided between the lower node N4 of each sense amplifier 110 and the lower output terminal S2 of the drive circuit 190. The disconnection transistors 141 are P-channel MOS transistors, and a control signal CUTP is supplied in common to gate electrodes of these transistors. On the other hand, the disconnection transistors 142 are N-channel MOS transistors, and a control signal CUTN is supplied in common to gate electrodes of these transistors.

Each disconnection transistor 141 and each disconnection transistor 142 constitute a disconnection means that disconnects each sense amplifier 110 from the drive circuit 190. When the control signal CUTP becomes a high level and when the control signal CUTN becomes a low level, each sense amplifier 110 is disconnected from the drive circuit 190. On the other hand, when the control signal CUTP becomes a low level and when the control signal CUTN becomes a high level, the higher node N3 of each sense amplifier 110 and the higher output terminal S1 of the drive circuit 190 are short-circuited, and the lower node N4 of each sense amplifier 110 and the lower output terminal S2 of the drive circuit 190 are short-circuited. Therefore, each sense amplifier 110 can receive an operation potential and a precharge potential VBL.

The circuit configuration of the relevant part of the semiconductor device 100 according to the present embodiment has been explained above. The operation of the semiconductor device 100 according to the present embodiment is explained next.

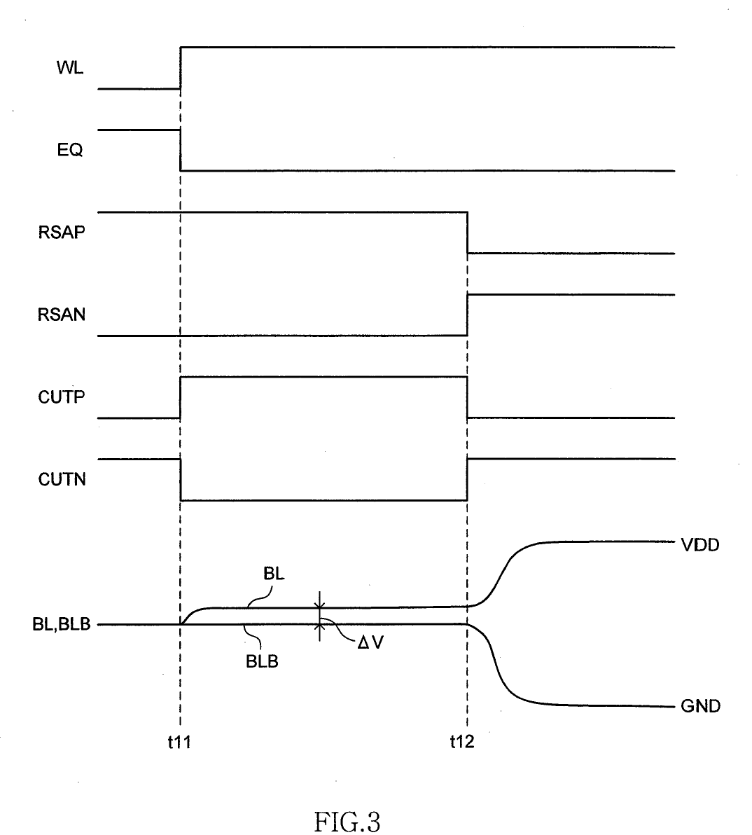

FIG. 3 is a timing diagram for explaining the operation of the semiconductor device 100 according to the present embodiment. In actual practice, since a certain time is necessary for a potential change of each control signal (WL, EQ, RSAP, RSAN, CUTP, and CUTN), a waveform of potential that changes appears with a predetermined inclination. However, in FIG. 3, time necessary for a potential change of each control signal is omitted, and the waveform of changed potential is shown vertically.

First, before data is read (before time t11), the word line WL is at a low level. Therefore, the potentials of the bit line BL and the inverted bit line BLB are both maintained at a precharge level (=VBL). During this period, the control signal CUTP is at a low level, and the control signal CUTN is at a high level. Therefore, the disconnection transistors 141 and 142 are both in the on state. Consequently, each sense amplifier 110 is connected to the drive circuit 190. During this period, the control signal EQ is at a high level, and the equalizer 130 is active. Therefore, each sense amplifier 110 is equalized to the precharge potential VBL by the equalizer 130 via the higher node N3 and the lower node N4.

In other words, since the sense amplifier 110 uses the signal nodes N1 and N2 as mutual reference potentials, equalization of the signal nodes N1 and N2, that is, equalization of the sense amplifier, is an essential operation. A circuit (not shown) similar to the equalizer 130 sets the signal nodes N1 and N2 to the same potential.

Further, in the present embodiment, the equalizer 130 equalizes the potentials of the higher output terminal S1 and the lower output terminal S2 to the precharge potential VBL. When the disconnection transistors 141 and 142 are turned on in this state, the sense amplifier can be equalized. The disconnection transistors 141 and 142 do not need to be in the on state during the whole period when the equalizer 130 is activated. Instead, it is sufficient that the disconnection transistors 141 and 142 are in the on state during at least a part of the period when the equalizer 130 is activated.

Next, the word line WL is activated to a high level at time t11, thereby starting a data reading and changing the control signal EQ to a low level. As a result, the equalizer 130 is inactivated. With this arrangement, a difference ΔV occurs between the potential of the bit line BL and the potential of the inverted bit line BLB. In FIG. 3, the potential of the bit line BL increases by ΔV. At this time, since the control signal RSAP maintains at a high level, and the control signal RSAN maintains at a low level, amplification operation is not performed yet.

In the case where the threshold voltages of the transistors 111 to 114 that constitute the sense amplifier 110 are lower than ΔV, particularly in the case where the threshold voltages are near 0 volt, one of the transistors 111 to 114 is turned on by the potential difference ΔV generated between the signal nodes N1 and N2.

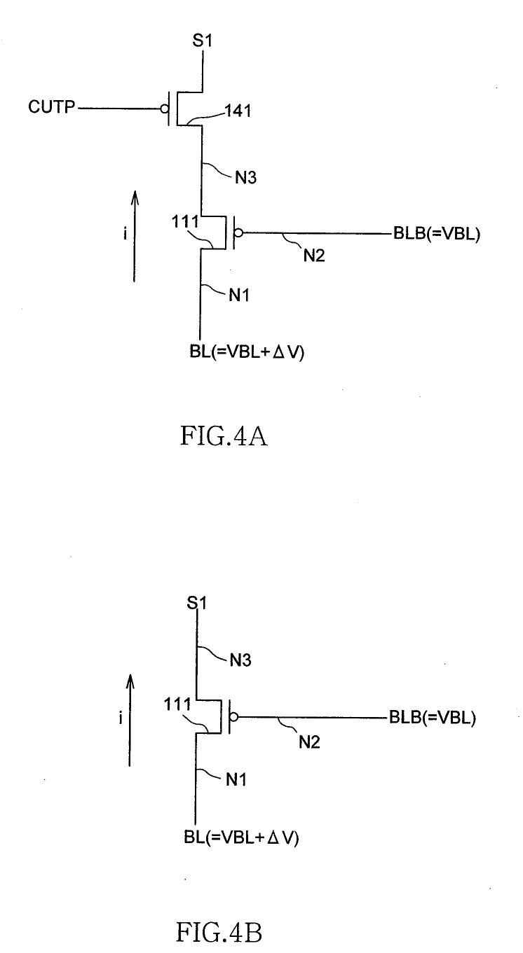

Assume that the potential of the bit line BL increases by ΔV from the precharge potential VBL (=VBL+ΔV) , and that the potential of the inverted bit line BLB is maintained at the precharge potential VBL, due to the activation of the word line WL. In this case, as shown in FIG. 4A that shows a part of the sense amplifier 110, potential of the P-channel MOS transistor 111 exceeds the threshold voltage, and therefore, is unnecessarily turned on. Consequently, charge (current i) flows out from the bit line BL toward the higher output terminal S1 of the drive circuit 190, and the potential of the bit line BL decreases.

In this case, assume that that the disconnection transistor 141 is not present and that the P-channel MOS transistor 111 is directly connected to the higher output terminal S1 of the drive circuit 190, as shown in FIG. 4B as a comparative example. Since many sense amplifiers 110 are connected in common to the higher output terminal S1 of the drive circuit 190 and the capacitance is relatively high, much charge on the bit line BL flows out to the higher output terminal S1 of the drive circuit 190. As a result, the potential of the bit line BL gradually decreases. Further, there is a possibility that the sense amplifiers 110 cannot perform amplification. In other words, data will be destroyed.

However, as shown in FIG. 4A, when the disconnection transistor 141 is provided between the higher node N3 of the sense amplifier 110 and the higher output terminal S1 of the drive circuit 190, and when this is set to the off state during the concerned period, the outflow of charge from the bit line BL stops immediately. Specifically, the P-channel MOS transistor 111 is turned off when the potential of the bit line BL (=signal node N1) and the potential of the higher node N3 coincide with each other due to the outflow of charge. There is no more outflow of charge. As a result, decrease of the potential of the bit line BL can be minimized.

The phenomenon that transistors are unnecessarily turned on also occurs in other transistors 112 to 114 that constitute the sense amplifiers 110. In other words, when the potential of the bit line BL is maintained at the precharge potential VBL and when the potential of the inverted bit line BLB increases by ΔV from the precharge potential VBL (=VBL+ΔV) , charge flows out from the inverted bit line BLB and the potential of the inverted bit line BLB decreases due to the turning-on of the P-channel MOS transistor 113.

When the potential of the bit line BL decreases by ΔV from the precharge potential VBL (=VBL−ΔV) and when the potential of the inverted bit line BLB is maintained at the precharge potential VBL, charge flows into the bit line BL and the potential of the bit line BL increases due to the turning-on of the N-channel MOS transistor 112. When the potential of the bit line BL is maintained at the precharge potential VBL and when the potential of the inverted bit line BLB decreases by ΔV from the precharge potential VBL (=VBL−ΔV), charge flows into the inverted bit line BLB and the potential of the inverted bit line BLB increases due to the turning-on of the N-channel MOS transistor 114.

In the above cases, when the disconnection transistors 141 and 142 are provided and also when these disconnection transistors are set to the off state during the concerned period, outflow and inflow of charge from the bit line BL and the inverted bit line BLB can be stopped immediately. In order to achieve this, according to the present embodiment, at time t11, the control signal CUTP is set to a high level and the control signal CUTN is set to a low level, thereby disconnecting each sense amplifier 110 from the drive circuit 190.

Next, at time t12, the control signal CUTP is changed to a low level, and the control signal CUTN is changed to a high level, thereby connecting each sense amplifier 110 to the drive circuit 190. The control signal RSAP is changed to a low level, and the control signal RSAN is changed to a high level, thereby supplying the operation potential to activate the sense amplifiers 110.

As a result, the potential difference ΔV between the signal nodes N1 and N2 is amplified. One of the potential of the bit line BL and the potential of the inverted bit line BLB increases to the power supply potential VDD, and the potential of the other bit line decreases to the ground potential GND. The amplification operation by the sense amplifiers 110 thus ends.

As described above, in the present embodiment, the disconnection transistors 141 and 142 are provided between each sense amplifier 110 and the drive circuit 190. During a period from when the word line WL is activated till when the sense amplifiers 110 are activated, the disconnection transistors 141 and 142 are set to the off state. Therefore, outflow and inflow of charge from the bit line BL and the inverted bit line BLB can be stopped immediately.

As a result, even when the threshold voltages of the transistors 111 to 114 that constitute each sense amplifier 110 are decreased to near 0 volt to increase the speed of the amplification operation with higher sensitivity, data destruction due to the unnecessary turning-on of the transistors 111 to 114 can be effectively prevented.

In the above embodiment, although the disconnection transistors 141 and 142 are set to the off state during the whole period from when the word line WL is activated till when the sense amplifiers 110 are activated, the present invention is not limited to this arrangement. Alternatively, the disconnection transistors 141 and 142 can be set to the off state during at least a part of the period from when the word line WL is activated till when the sense amplifiers 110 are activated.

However, in order to sufficiently decrease the outflow and inflow of charge, it is preferable to set the disconnection transistors 141 and 142 to the off state during a main part of the period from when the word line WL is activated till when the sense amplifiers 110 are activated. Most preferably, the disconnection transistors 141 and 142 are set to the off state during substantially the whole period from when the word line WL is activated till when the sense amplifiers 110 are activated, like in the above embodiment.

While one disconnection transistor 141 and one disconnection transistor 142 are provided corresponding to each sense amplifier 110 in the above embodiment, one disconnection transistor 141 and one disconnection transistor 142 can be assigned to plural sense amplifiers 110.

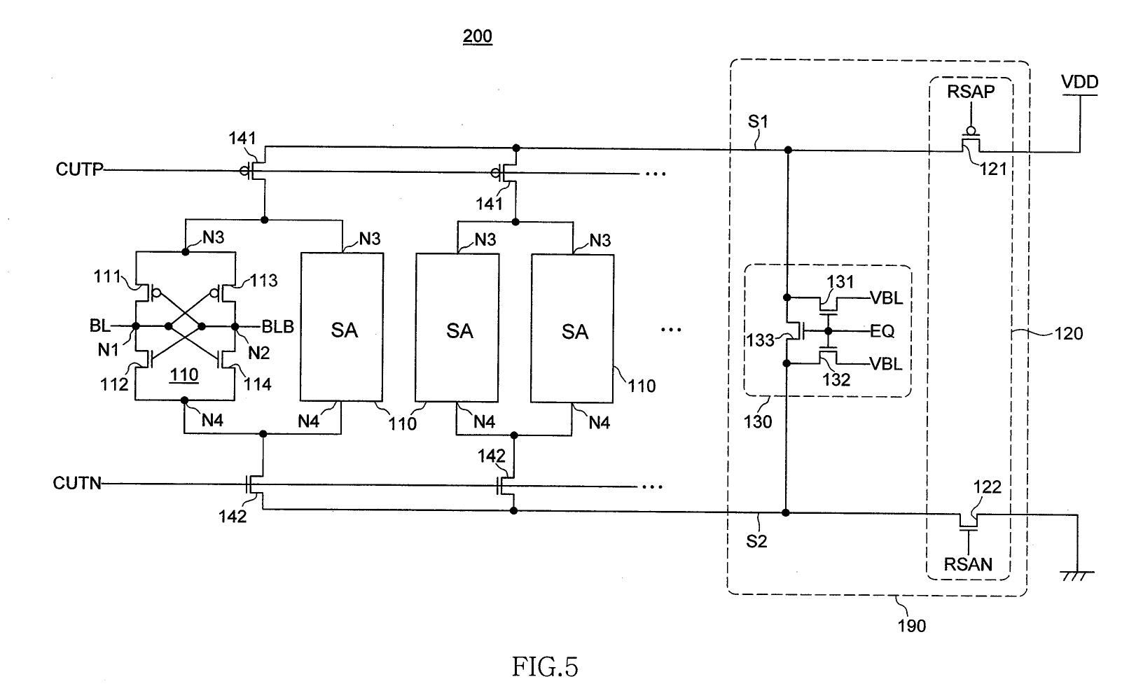

FIG. 5 is a circuit diagram showing relevant parts of a semiconductor device 200 in which one disconnection transistor 141 and one disconnection transistor 142 are assigned to two sense amplifiers 110. As shown in FIG. 5, even when one disconnection transistor 141 and one disconnection transistor 142 are assigned to the two sense amplifiers 110 in the semiconductor device 200, effects similar to those of the above embodiment can be obtained when the disconnection transistors 141 and 142 are set to the off state during at least a part of the period from when the word line WL is activated till when the sense amplifiers 110 are activated.

One disconnection transistor 141 and one disconnection transistor 142 can be assigned to not only the two sense amplifiers 110, but also to three or more sense amplifiers 110. When one disconnection transistor 141 and one disconnection transistor 142 are assigned to more sense amplifiers 110, more charge flows out and flows in. Considering this fact and that the disconnection transistors 141 and 142 with a very small size can be used, it is preferable to assign one disconnection transistor 141 and one disconnection transistor 142 to a small number of sense amplifiers 110.

Most preferably, one disconnection transistor 141 and one disconnection transistor 142 are assigned to each one sense amplifier 110.

While the disconnection transistor 141 is connected to the higher node N3 of the sense amplifier 110 and the disconnection transistor 142 is connected to the lower node N4 of the sense amplifier 110 in the above embodiment, one of these connections can be omitted. This is effective when there is a difference between a deviation in the threshold voltages of the P-channel MOS transistors 111 and 113 and a deviation in the threshold voltages of the N-channel MOS transistors 112 and 114, among the transistors that constitute each sense amplifier 110.

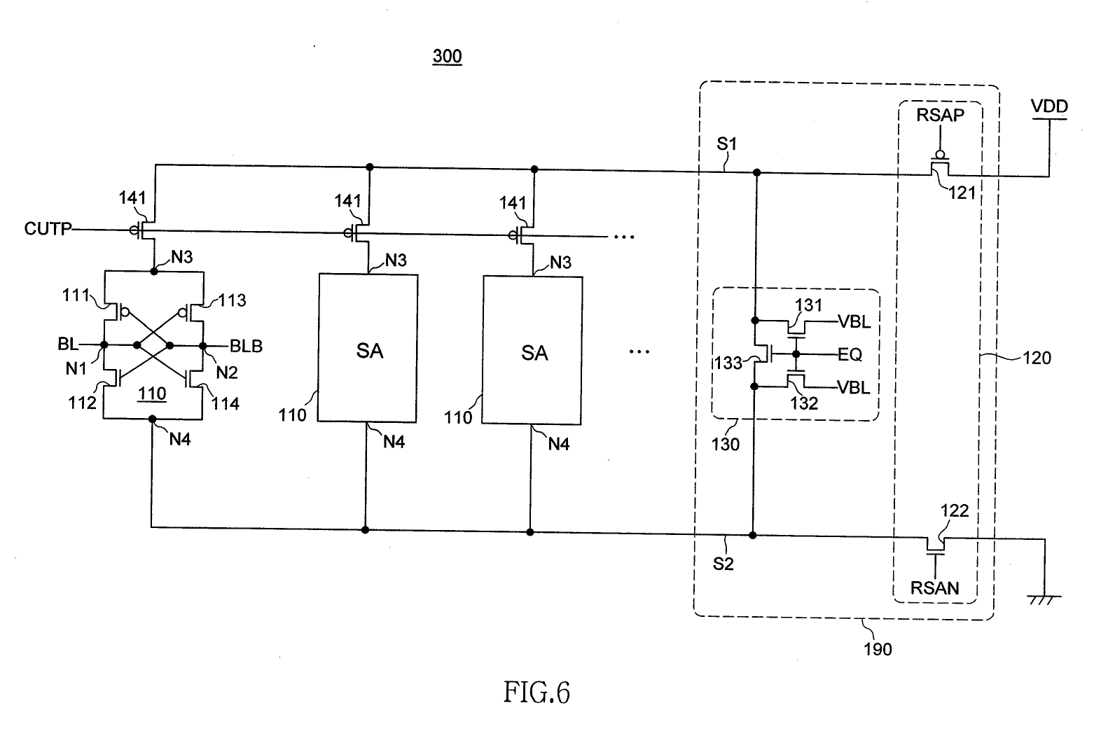

FIG. 6 is a circuit diagram showing relevant parts of a semiconductor device 300 from which the disconnection transistor 142 is omitted.

According to this example, outflow of charge from the bit line BL and the inverted bit line BLB to the higher output terminal SI of the sense amplifier 110 can be suppressed. However, flow of charge from the lower output terminal S2 into the bit line BL and the inverted bit line BLB cannot be suppressed.

According to this semiconductor device 300, a deviation in the threshold voltages of the P-channel MOS transistors 111 and 113 is larger than a deviation in the threshold voltages of the N-channel MOS transistors 112 and 114. Therefore, this semiconductor device 300 is effective particularly when the outflow of charge to the higher output terminal S1 is more significant than the inflow of charge from the lower output terminal S2.

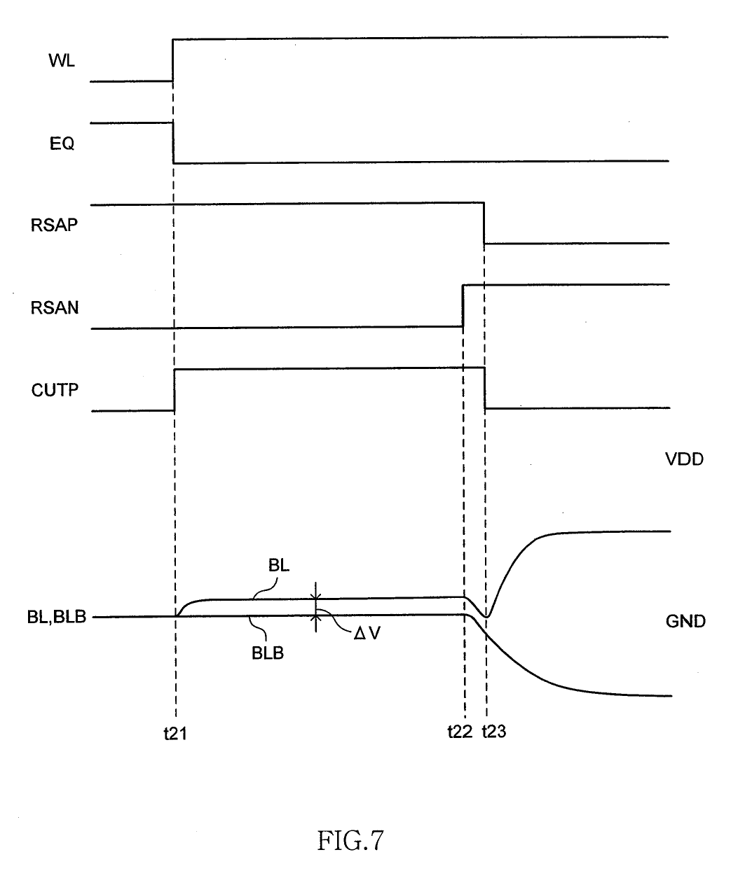

When a deviation in the threshold voltages of the P-channel MOS transistors 111 and 113 is large, it is effective to activate the control signal RSAN before the control signal RSAP, thereby stabilizing the operation of the sense amplifiers 110, as shown in a timing diagram in FIG. 7.

In performing this operation, as shown in FIG. 7, during a period from when the control signal RSAN is activated (time t22) till when the control signal RSAP is activated (time t23), potentials of the bit line BL and the inverted bit line BLB, that is, gate potentials of the P-channel MOS transistors 111 and 113, decrease. As a result, during this period, outflow of charge to the higher output terminal S1 is accelerated in some cases. However, even when this operation is performed, outflow of charge to the higher output terminal S1 can be effectively suppressed by connecting the disconnection transistor 141 to the higher node N3 of the sense amplifier 110, like the semiconductor device 300 shown in FIG. 6.

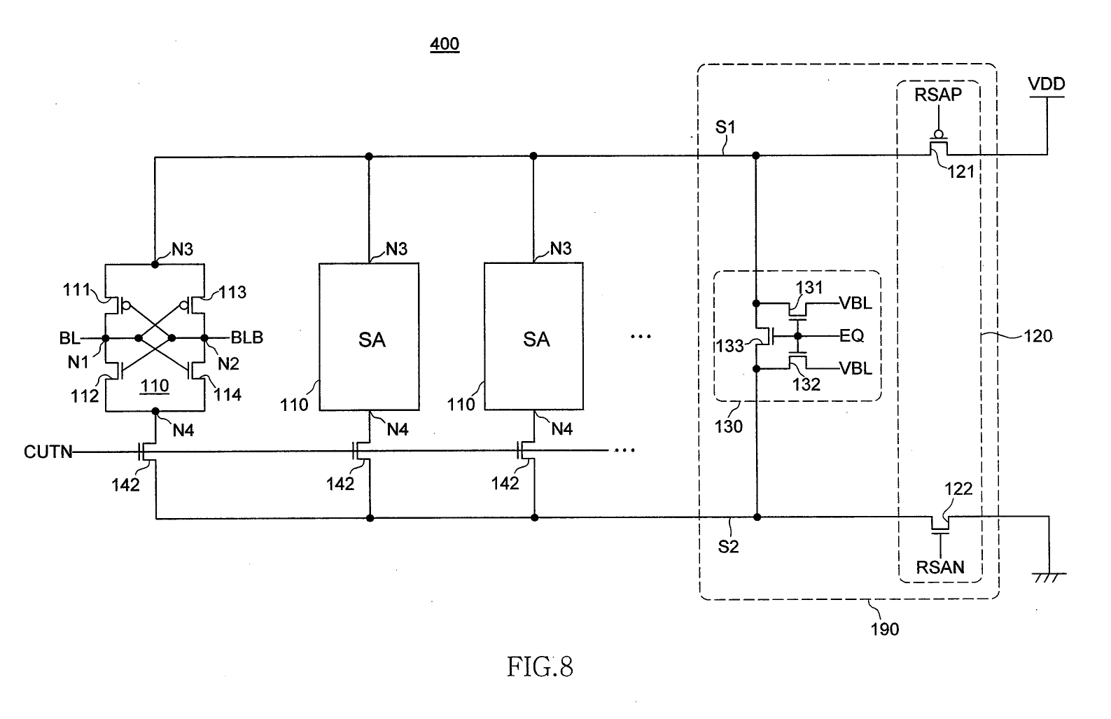

On the other hand, FIG. 8 is a circuit diagram showing relevant parts of a semiconductor device 400 from which the disconnection transistor 141 is omitted.

According to this example, flow of charge from the lower output terminal S2 into the bit line BL and the inverted bit line BLB can be suppressed. However, outflow of charge from the bit line BL and the inverted bit line BLB to the higher output terminal S1 of the sense amplifiers 110 cannot be suppressed.

According to this semiconductor device 400, a deviation in the threshold voltages of the N-channel MOS transistors 112 and 114 is larger than a deviation in the threshold voltages of the P-channel MOS transistors 111 and 113. Therefore, this semiconductor 400 is effective particularly when the inflow of charge from the lower output terminal S2 is more significant than the outflow of charge to the higher output terminal S1.

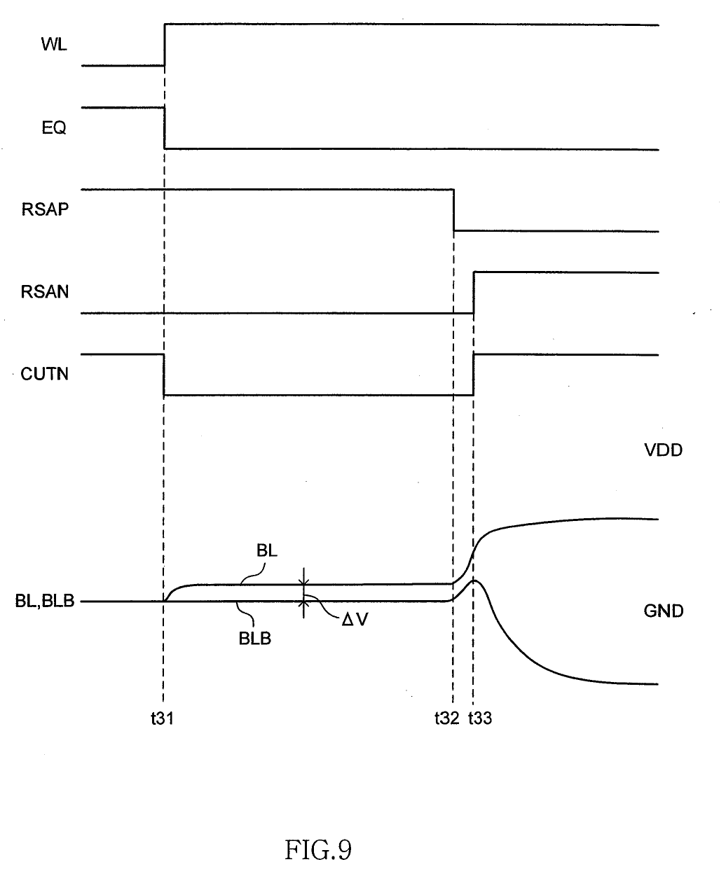

When a deviation in the threshold voltages of the N-channel MOS transistors 112 and 114 is large, it is effective to activate the control signal RSAP before the control signal RSAN, thereby stabilizing the operation of the sense amplifiers 110, as shown in a timing diagram in FIG. 9.

In performing this operation, as shown in FIG. 9, during a period from when the control signal RSAP is activated (time t32) till when the control signal RSAN is activated (time t33), potentials of the bit line BL and the inverted bit line BLB, that is, gate potentials of the N-channel MOS transistors 112 and 114, decrease.

As a result, during this period, inflow of charge from the lower output terminal S2 is accelerated in some cases. However, even when this operation is performed, inflow of charge from the lower output terminal S2 can be effectively suppressed by connecting the disconnection transistor 142 to the lower node N4 of the sense amplifier 110, like the semiconductor device 400 shown in FIG. 8.

Further, the semiconductor device according to the present invention has an advantage in that the evaluation test of current leak (bit line leak) that occurs in the bit line BL and the inverted bit line BLB can be conducted more accurately. In other words, the evaluation test of the bit line leak is conducted by increasing the period from when the word line WL is activated (see time t11 in FIG. 3) till when the sense amplifier 110 is activated (see time t12 in FIG. 3), from the normal operation period.

As described above, according to the conventional practice, it is not possible to determine whether a reduction in the potential of the bit line BL and the inverted bit line BLB along the lapse of time is due to the current leak or due to the outflow of charge to the sense amplifiers 110. Even when reduction in the potential of the bit line BL and the inverted bit line BLB is small in this test, there is a possibility that the bit line leak is compensated for by the charge inflow from the sense amplifiers 110.

However, according to the semiconductor device of the present invention, the sense amplifiers 110 can be disconnected from the drive circuit 190 during at least a part of the period from when the word line WL is activated till when the sense amplifiers 110 are activated. Therefore, the bit line leak can be evaluated in higher precision.

As explained above, according to the present invention, the disconnector can disconnect the sense amplifier from the drive circuit. Therefore, by disconnecting between the sense amplifier and the drive circuit during at least a part of the period from when the word line is activated till when the sense amplifier is activated, outflow of charge from the bit line and flow of charge into the bit line can be immediately stopped.

As a result, even when threshold voltages of transistors that constitute the sense amplifier are decreased to near 0 volt to increase the speed of the amplification operation with higher sensitivity, destruction of data due to an unnecessary turning-on of the transistors can be effectively prevented.

Since outflow and inflow of charge from and into the bit line can be effectively suppressed, current leak that occurs in the bit line can be evaluated in high precision.

The present invention is in no way limited to the aforementioned embodiments, but rather various modifications are possible within the scope of the invention as recited in the claims, and naturally these modifications are included within the scope of the invention.

1-18. (canceled)

19. A semiconductor device, comprising:
a word line;
a bit line;
a memory cell that is connected to the bit line when the word line is activated;
a sense amplifier that is connected to the bit line;
an activating circuit that activates the sense amplifier by supplying an operation voltage to the sense amplifier;
an equalizer that equalizes the sense amplifier; and
a disconnector that disconnects the sense amplifier from the activating circuit,
wherein the disconnector changes from a connecting state to a disconnecting state in response to a change of the equalizer from an inactive state to an active state, and changes from the disconnecting state to the connecting state in response to a change of the activating circuit from an inactive state to an active state.

20. The semiconductor device according to claim 19, wherein
the sense amplifier comprises:
a signal node connected to the bit line;
a higher node to which a first operating voltage necessary for amplification is supplied; and
a lower node to which a second operating voltage necessary for amplification is supplied,
the activating circuit comprises:
a higher output terminal that supplies the first operating voltage; and
a lower output terminal that supplies the second operating voltage, and
the disconnector comprises a first disconnecting transistor that is connected between the higher node of the sense amplifier and the higher output terminal of the activating circuit.

21. The semiconductor device according to claim 20, wherein
a plurality of sense amplifiers are commonly connected to the higher and lower output terminals of the activating circuit, and
a plurality of the first disconnecting transistors are connected between the higher node of each of the sense amplifiers and the higher output terminal of the activating circuit.

22. The semiconductor device according to claim 20, wherein
a plurality of sense amplifiers are commonly connected to the higher and lower output terminals of the activating circuit, and
the first disconnecting transistor is connected between the higher output terminal of the activating circuit and a node to which the plurality of sense amplifiers are commonly connected.

23. The semiconductor device according to claim 19, wherein
the sense amplifier comprises:
a signal node connected to the bit line;
a higher node to which a first operating voltage necessary for amplification is supplied; and
a lower node to which a second operating voltage necessary for amplification is supplied,
the activating circuit comprises;
a higher output terminal that supplies the first operating voltage; and
a lower output terminal that supplies the second operating voltage, and
the disconnector comprises a second disconnecting transistor that is connected between the lower node of the sense amplifier and the lower output terminal of the activating circuit.

24. The semiconductor device according to claim 23, wherein
a plurality of sense amplifiers are commonly connected to the higher and lower output terminals of the activating circuit, and
a plurality of the second disconnecting transistors are connected between the lower node of each of the sense amplifiers and the lower output terminal of the activating circuit.

25. The semiconductor device according to claim 23, wherein
a plurality of sense amplifiers are commonly connected to the higher and lower output terminals of the activating circuit, and
the second disconnecting transistor is connected between the lower output terminal of the activating circuit and a node to which the plurality of sense amplifiers are commonly connected.

26. The semiconductor device according to claim 19, wherein the first operating voltage is power supply potential VDD, and the second operating voltage is ground potential GND.

27. The semiconductor device according to claim 20, wherein said activating circuit further comprises a first activating transistor that is connected between the first operating voltage terminal and the higher output terminal, and a second activating transistor that is connected between the second operating voltage terminal and the lower output terminal.

28. The semiconductor device according to claim 27, wherein
the second activating transistor is set to a conductive state before the first activating transistor, and
the first disconnecting transistor changes from the disconnecting state to the connecting state in response to a change of the first activating transistor from a disconnecting state to the conductive state.

29. The semiconductor device according to claim 23, wherein said activating circuit further comprises a first activating transistor that is connected between the first operating voltage terminal and the higher output terminal, and a second activating transistor that is connected between the second operating voltage terminal and the lower output terminal.

30. The semiconductor device according to claim 29, wherein
the first activating transistor is set to a conductive state before the second activating transistor, and
the second disconnecting transistor changes from the disconnecting state to the connecting state in response to a change of the second activating transistor from a disconnecting state to the conductive state.

31. The semiconductor device according to claim 20, wherein there is no disconnector between the lower node of the sense amplifier and the lower output terminal of the activating circuit.

32. The semiconductor device according to claim 23, wherein there is no disconnector between the higher node of the sense amplifier and the higher output terminal of the activating circuit.
